(19) United States
(12) Patent Application Publication
(10) Pub. No.: US 2024/0306372 A1
(43) Pub. Date: Sep. 12, 2024

(54) DYNAMIC RANDOM ACCESS MEMORY AND METHOD OF FABRICATING THE SAME

(71) Applicant: Winbond Electronics Corp., Taichung City (TW)

(72) Inventor: Hsueh-Cheng Liao, Yunlin (TW)

(73) Assignee: Winbond Electronics Corp., Taichung City (TW)

(21) Appl. No.: 18/181,565

(22) Filed: Mar. 10, 2023

(51) Int. Cl. H10B 12/00

(52) U.S. Cl. CPC H10B 12/482; H10B 12/02; H10B 12/315; H10B 12/34

(57) ABSTRACT

Provided is a dynamic random access memory including: a plurality of word line structures, a plurality of bit line structures, a plurality of node contacts, and a plurality of spacers. The plurality of word line structures are located in a substrate. The plurality of bit line structures are located above the substrate and span the plurality of word line structures. Each of the plurality of node contacts is located between two adjacent word structures and two adjacent bit line structures. The plurality of spacers are located on a plurality of sidewalls of the plurality of node contacts. Top portions and bottom portions of two spacers of two adjacent node contacts are connected to each other to form a plurality of first air gaps.

### BACKGROUND OF THE INVENTION

### Field of the Invention

The invention relates to an integrated circuit and a method of fabricating the same, and in particular to a dynamic random access memory (DRAM) and a method of fabricating the same.

### Description of Related Art

With the rapid development of technology, in order to meet consumers' demand for miniaturized electronic devices, the size of a DRAM design is constantly shrinking, and the development thereof is leaning towards high density. However, as the size of elements continues to shrink, the influence of parasitic capacitance becomes more and more significant.

### SUMMARY OF THE INVENTION

The invention provides a dynamic random access memory (DRAM) and a method of fabricating the same that may reduce the parasitic capacitance between node contacts, so as to reduce the delay of resistors and capacitors.

A DRAM of an embodiment of the invention includes a plurality of word line structures, a plurality of bit line structures, a plurality of node contacts, and a plurality of spacers. The plurality of word line structures are located in a substrate. The plurality of bit line structures are located above the substrate and span the plurality of word line structures. Each of the plurality of node contacts is located between two adjacent word structures and two adjacent bit line structures. The plurality of spacers are located on a plurality of sidewalls of the plurality of node contacts. Top portions and bottom portions of two spacers of two adjacent node contacts are connected to each other to form a plurality of first air gaps.

A method of fabricating a DRAM of an embodiment of the invention includes the following steps. A plurality of word line structures located in a substrate are formed. A plurality of bit line structures located above the substrate are formed. A plurality of node contacts are formed. Each of the plurality of node contacts is located between two adjacent word structures and two adjacent bit line structures. A plurality of spacers located at a plurality of sidewalls of the plurality of node contacts are formed. Top portions and bottom portions of two spacers of two adjacent node contacts are connected to each other to form a plurality of first air gaps.

Based on the above, in an embodiment of the invention, forming the air gaps in the spacers where the capacitor nodes are in contact with the sidewalls of the nodes may reduce the parasitic capacitance between the node contacts, so as to reduce the delay of resistors and capacitors.

### BRIEF DESCRIPTION OF THE DRAWINGS

FIG. 1A to FIG. 1C are top views of a DRAM according to the first embodiment of the invention, which are schematic cross-sectional views along line I-I′ of FIG. 2A to FIG. 2J.

FIG. 2A to FIG. 2K are top views of a DRAM according to the first embodiment of the invention.

FIG. 3A to FIG. 3J are schematic cross-sectional views of section line A-A′ in FIG. 2A to FIG. 2J.

FIG. 4A to FIG. 4J are schematic cross-sectional views of section line B-B′ in FIG. 2A to FIG. 2J.

FIG. 5A to FIG. 5J are schematic cross-sectional views of section line C-C′ in FIG. 2A to FIG. 2J.

FIG. 6A to FIG. 6F are schematic cross-sectional views of intermediate processes of a method of fabricating a DRAM according to the invention.

### DESCRIPTION OF THE EMBODIMENTS

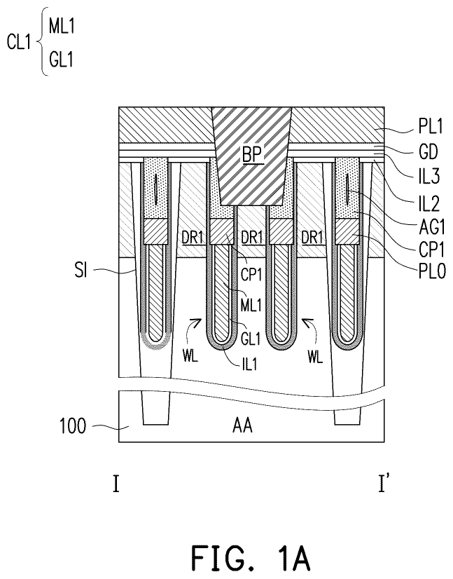

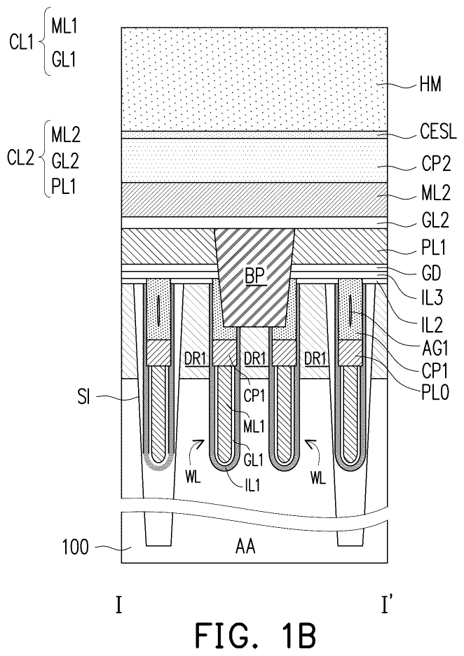

Referring to FIG. 1A, a substrate 100 is provided. The substrate 100 may be a semiconductor material, such as silicon or other suitable materials. A plurality of isolation structures SI are formed in the substrate 100. The material of the isolation structures SI includes silicon oxide, silicon nitride, or a combination thereof. The isolation structures SI define a plurality of active areas AA in the substrate 100. Insulation layers IL1 and IL2 are formed on the substrate 100 and the plurality of isolation structures SI. The insulating layers IL1 and IL2 are, for example, silicon oxide layers.

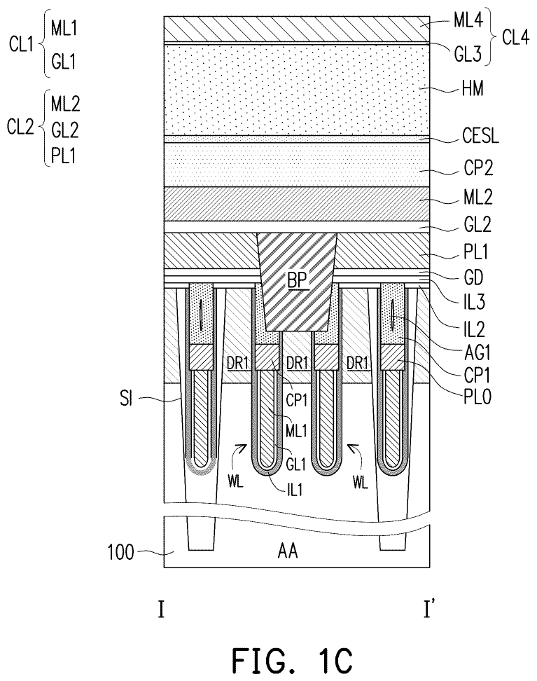

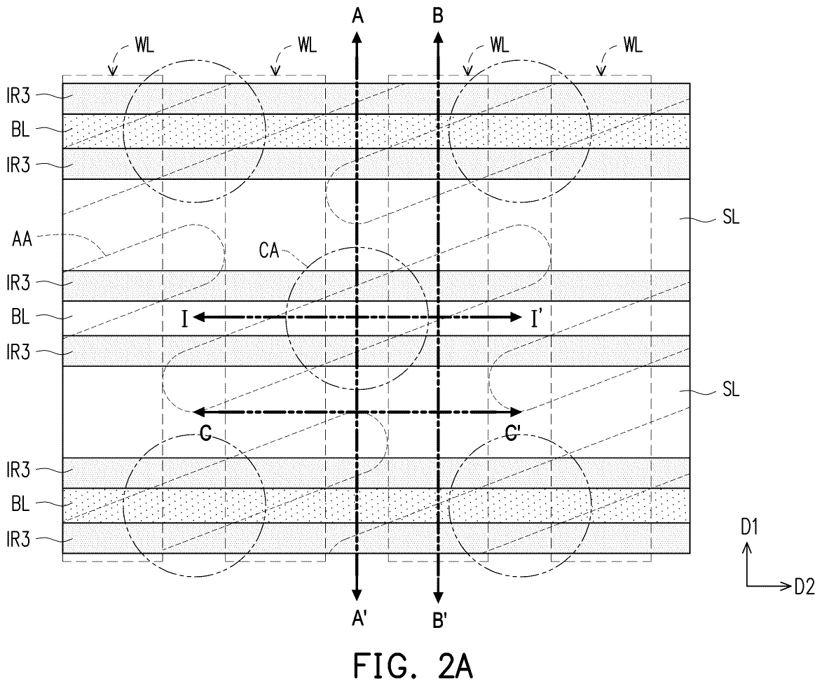

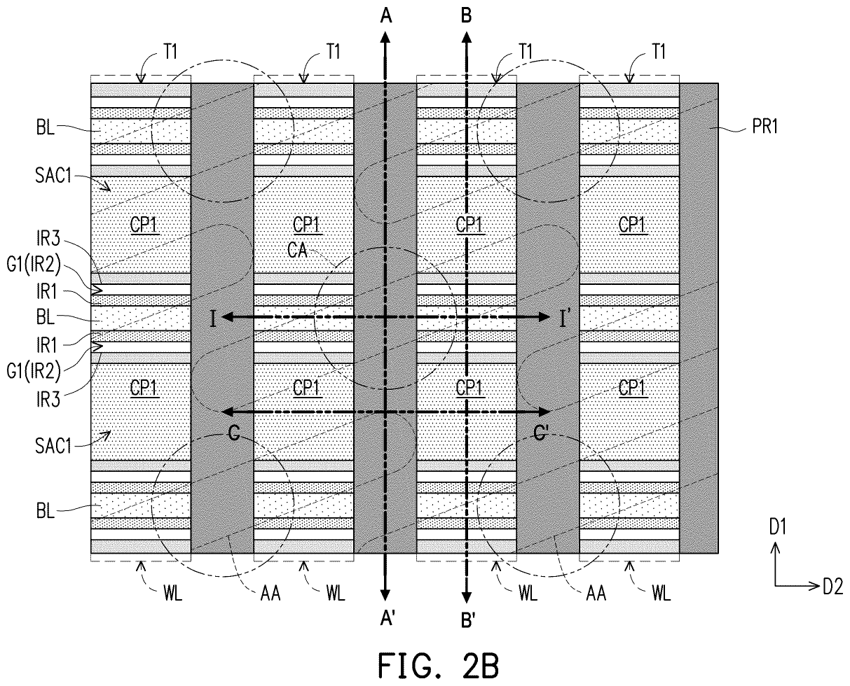

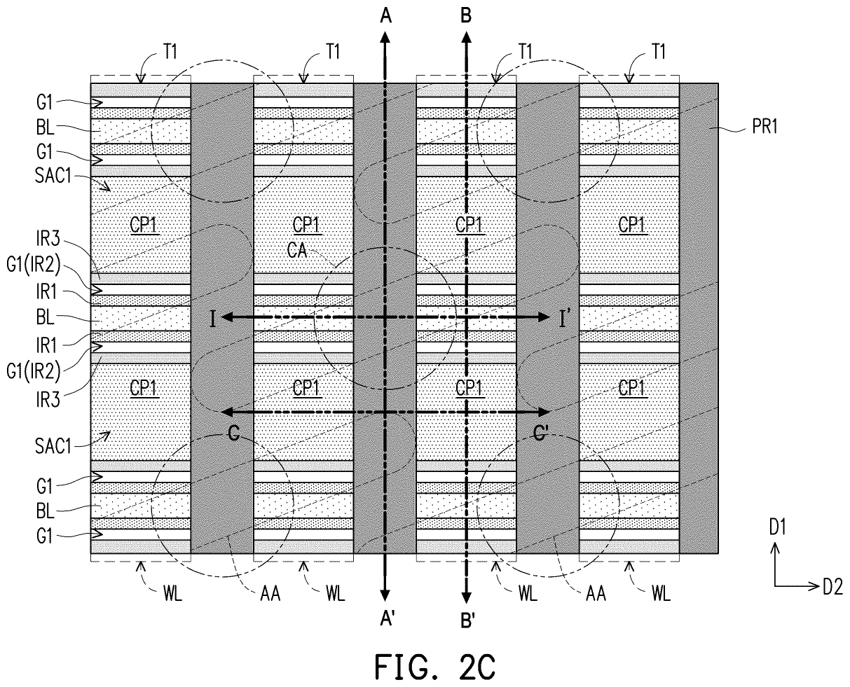

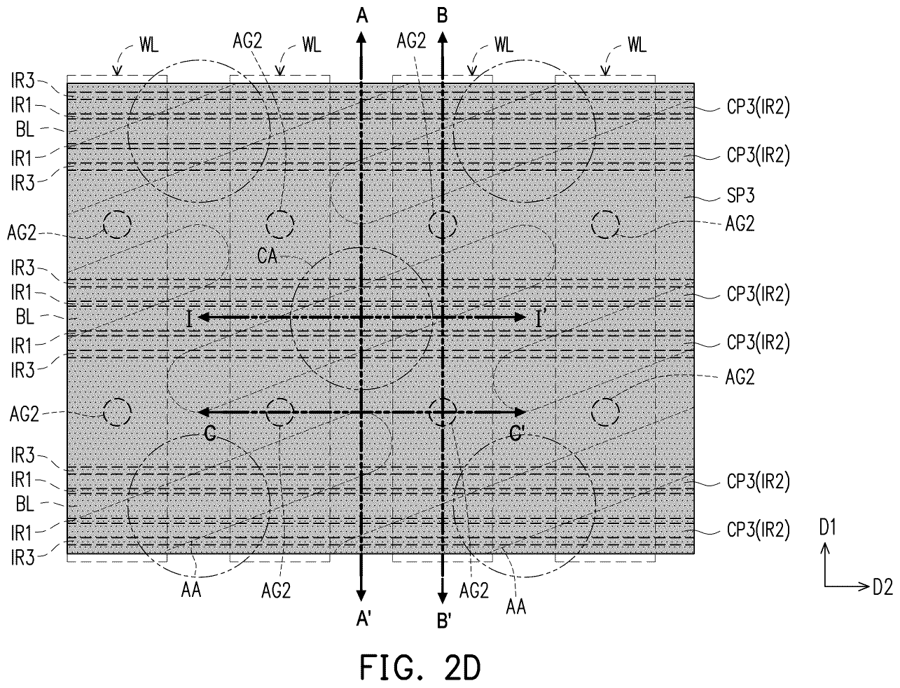

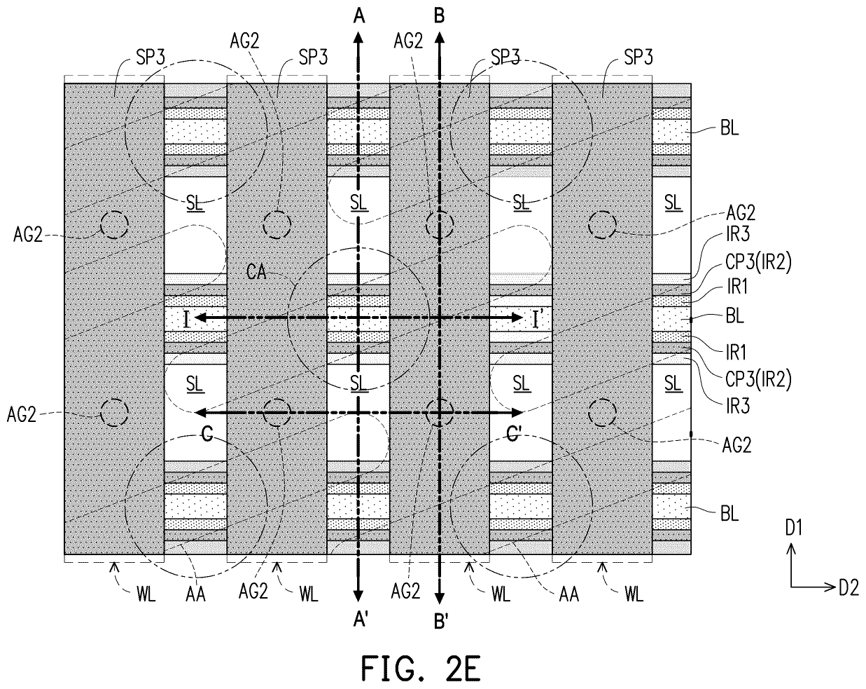

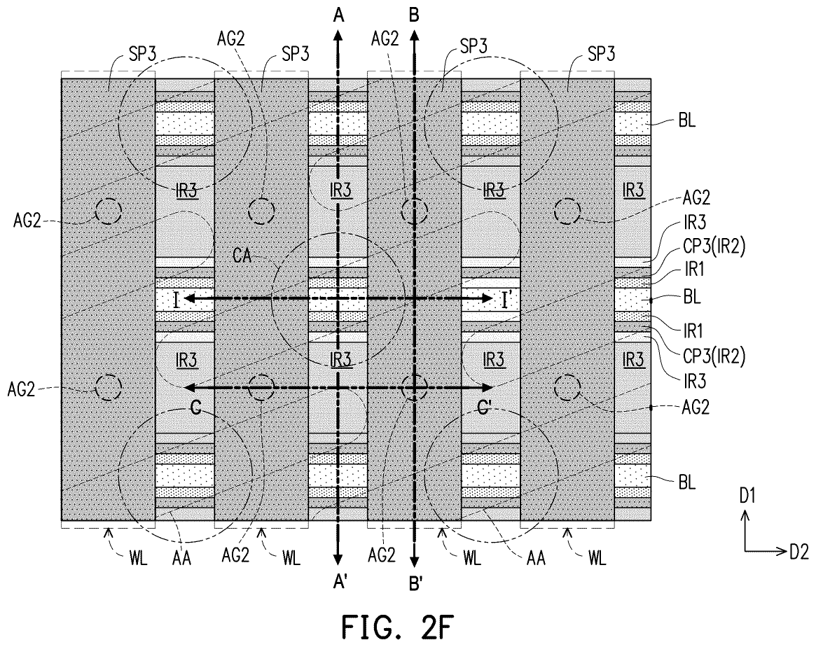

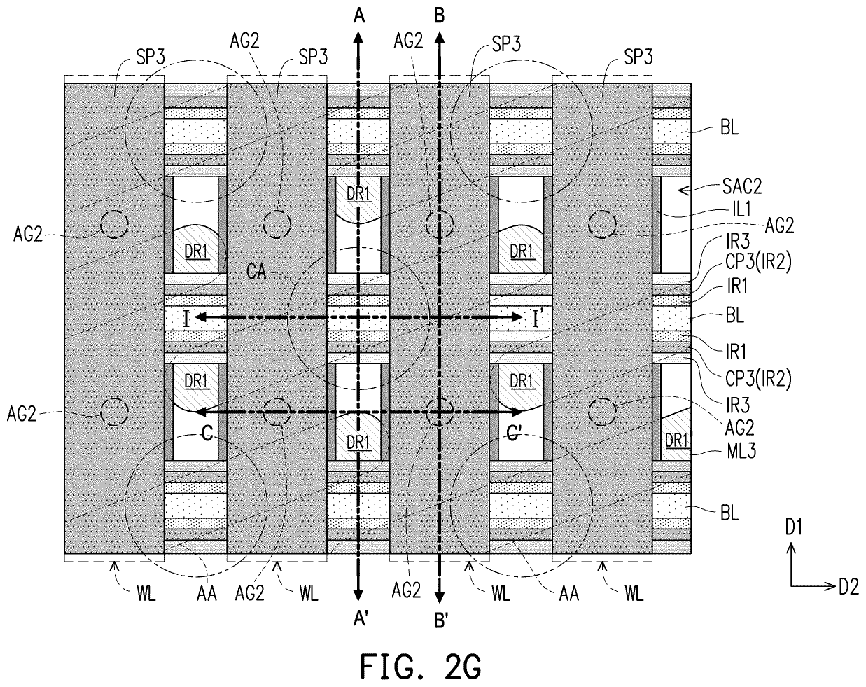

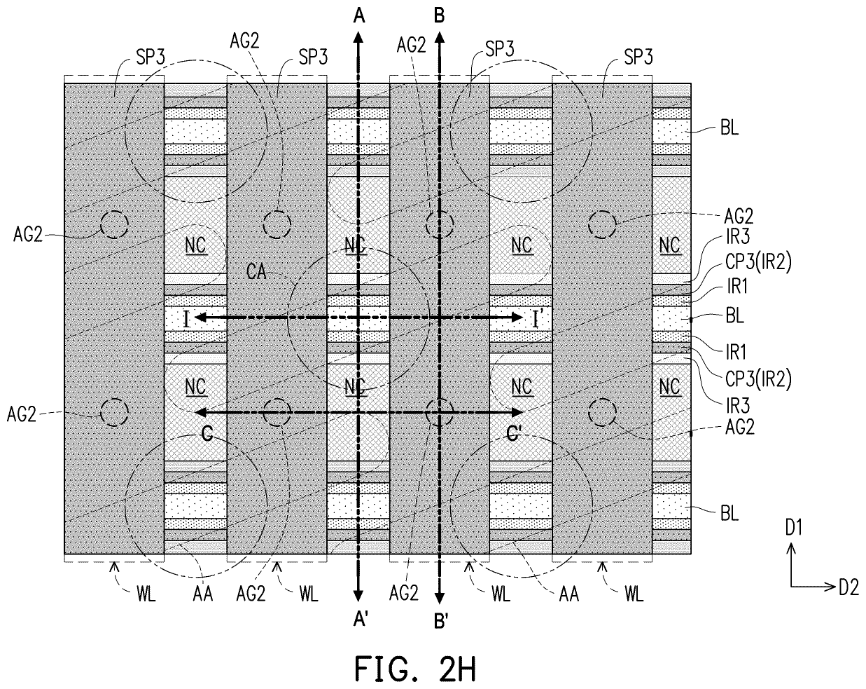

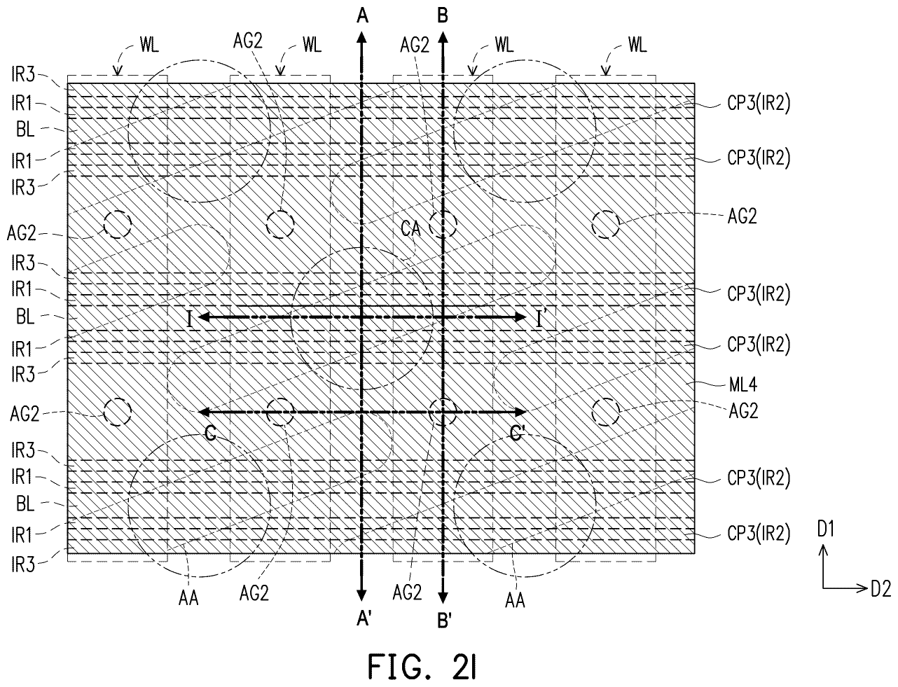

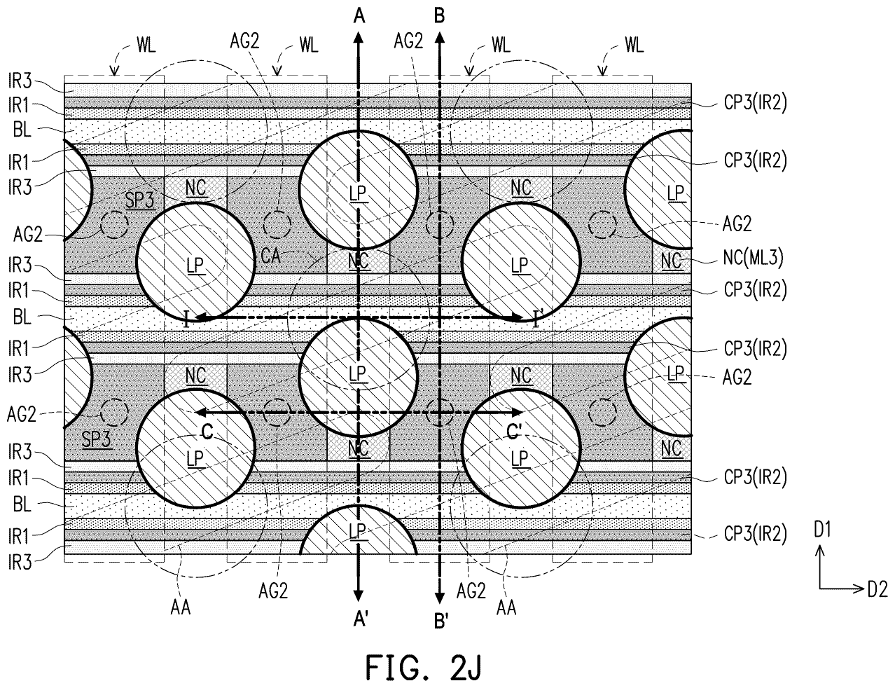

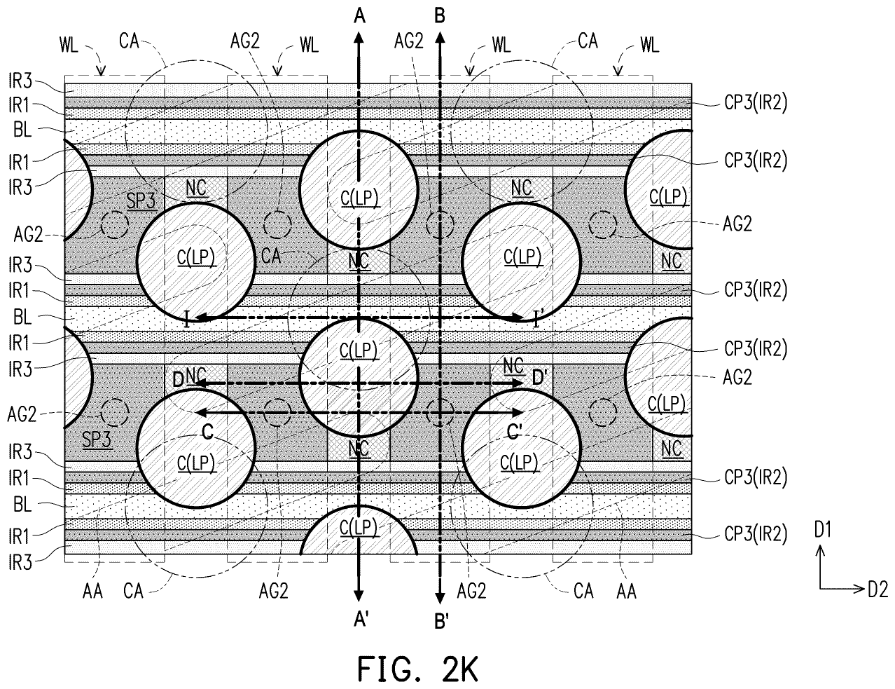

Referring to FIG. 1A and FIG. 2A, a plurality of word line structures WL are formed in the substrate 100. The word line structures WL pass through the insulating layer IL2 and the substrate 100. The word line structures WL are arranged along a direction D2 and respectively extended along a direction D1, passing through the active areas AA and the plurality of isolation structures SI. Each of the word line structures WL may include the insulating layer IL1, a conductor layer CL1, and a capping layer CP1, or optionally further include a semiconductor layer PL0. The insulating layer IL1 may be used as a gate dielectric layer. The insulating layer IL1 surrounds the conductor layer CL1, the semiconductor layer PL0, and the capping layer CP1. The insulating layer IL1 is, for example, silicon oxide. The conductor layer CL1 may include a metal layer ML1 and an adhesive layer GL1. The adhesive layer GL1 is located between the conductor layer CL1 and the insulating layer IL1. The metal layer ML1 is, for example, tungsten. The adhesive layer GL1 is, for example, titanium, titanium nitride, tantalum, tantalum nitride, or a combination thereof. The semiconductor layer PL0 is covered on the conductor layer CL1. The semiconductor layer PL0 is, for example, polysilicon. The capping layer CP1 is covered on the semiconductor layer PL0. The capping layer CP1 is, for example, silicon nitride.

Doped regions DR1 are formed in the active areas AA of the substrate 100. The doped regions DR1 may be used as source or drain regions. The substrate 100 has a dopant of a first conductivity type, for example, and the doped regions DR1 have a dopant of a second conductivity type, for example. In some embodiments, the dopant of the first conductivity type is, for example, a P-type dopant, and the dopant of the second conductivity type is, for example, an N-type dopant. The P-type dopant is, for example, boron, and the N-type dopant is, for example, phosphorus or arsenic.

An insulating layer IL3 is formed on the substrate 100. The insulating layer IL3 is, for example, a silicon nitride layer. Then, a dielectric layer GD and a semiconductor layer PL1 are formed on the substrate 100. The dielectric layer GD is, for example, a silicon oxide layer or a high-k dielectric material. The semiconductor layer PL1 is, for example, doped polysilicon. Then, a bit line plug BP is formed. The bit line plug BP penetrates through the semiconductor layer PL1, the dielectric layer GD, and the insulating layers IL3 and IL2, and is extended into the substrate 100 to be electrically connected to the doped regions DR1. The bit line plug BP includes doped polysilicon or metal.

Referring to FIG. 1B, a barrier layer GL2, a metal layer ML2, a capping layer CP2, an etch stop layer CESL, and a hard mask layer HM are formed above the substrate 100. The material of the barrier layer GL2 is, for example, titanium, titanium nitride, tantalum, tantalum nitride, tungsten silicide (WSi), tungsten nitride (WN), or a combination thereof. The metal layer ML2 may be metal or metal silicide, such as tungsten, tungsten silicide, cobalt silicide, or a combination thereof. The capping layer CP2 is, for example, silicon nitride. The etch stop layer CESL is, for example, silicon nitride. The hard mask layer HM is, for example, silicon nitride.

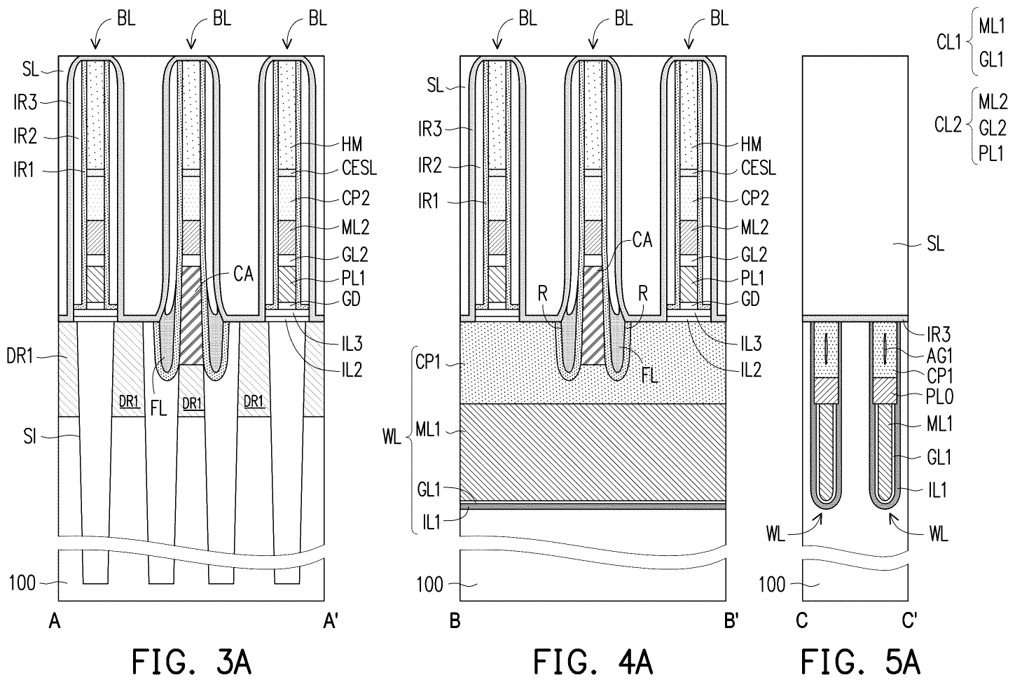

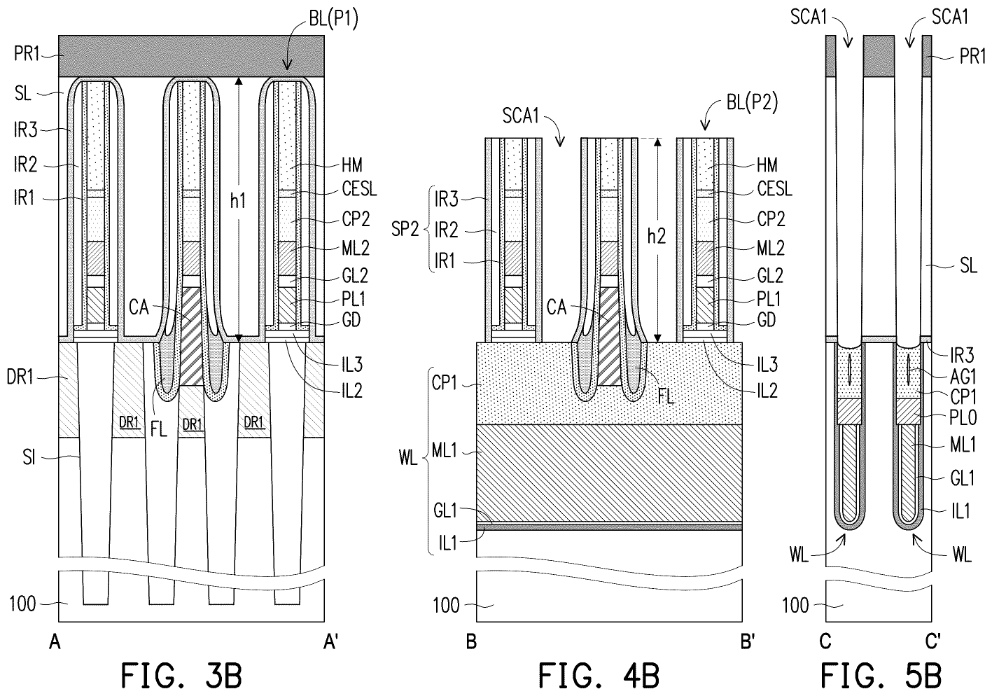

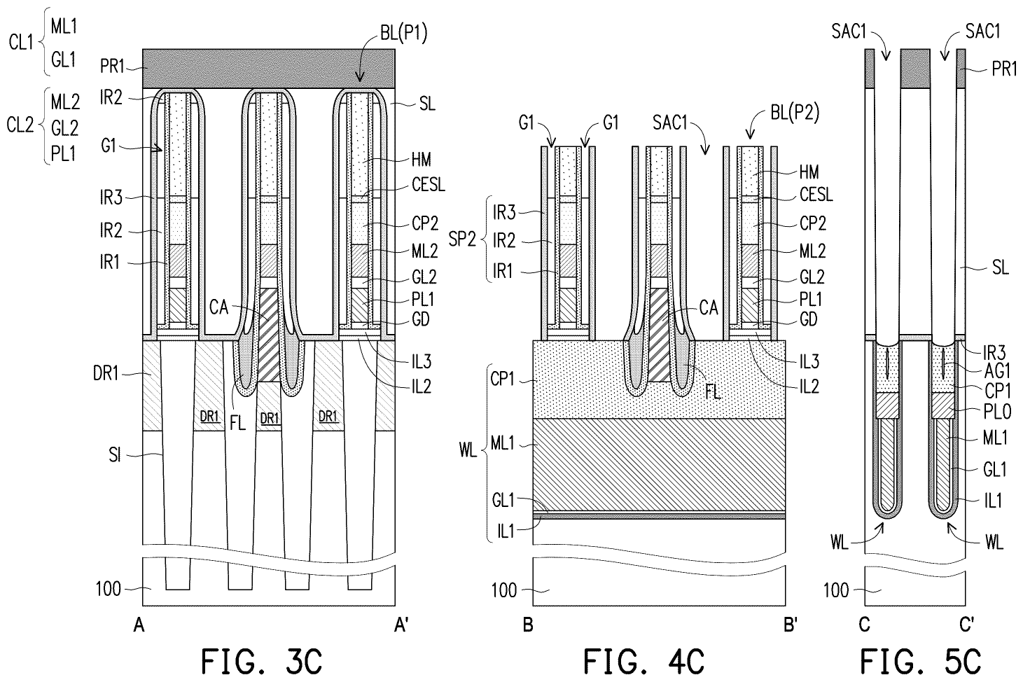

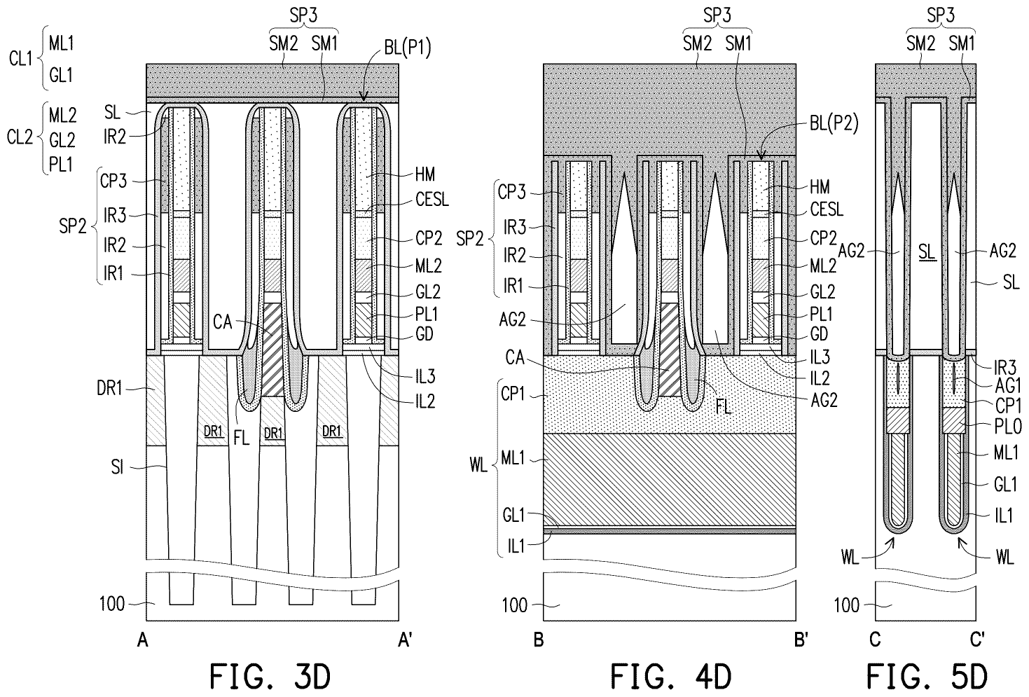

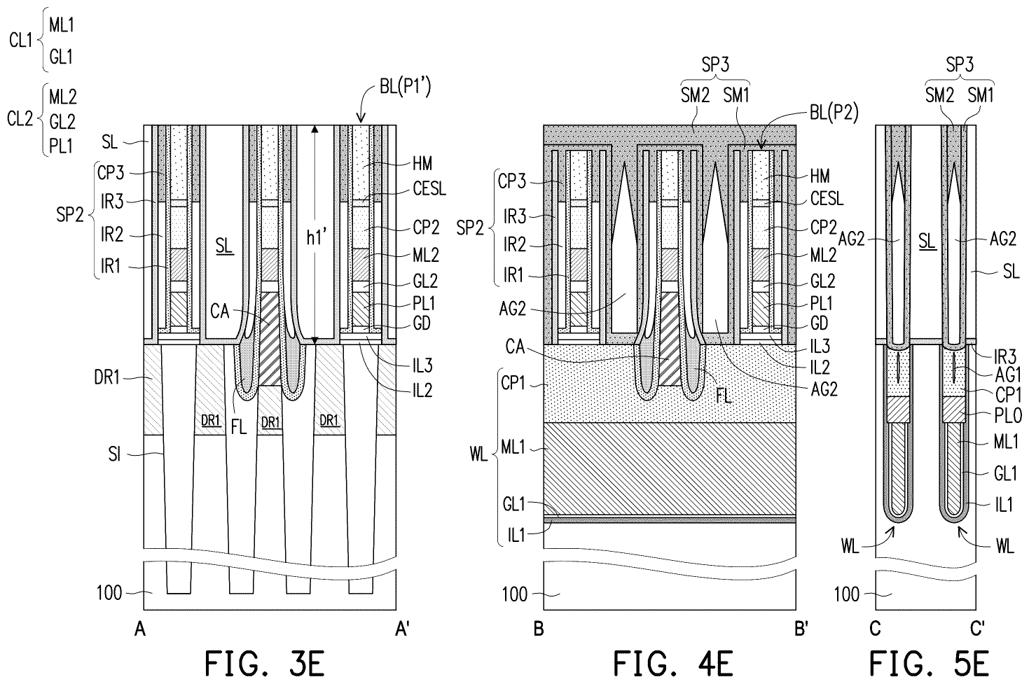

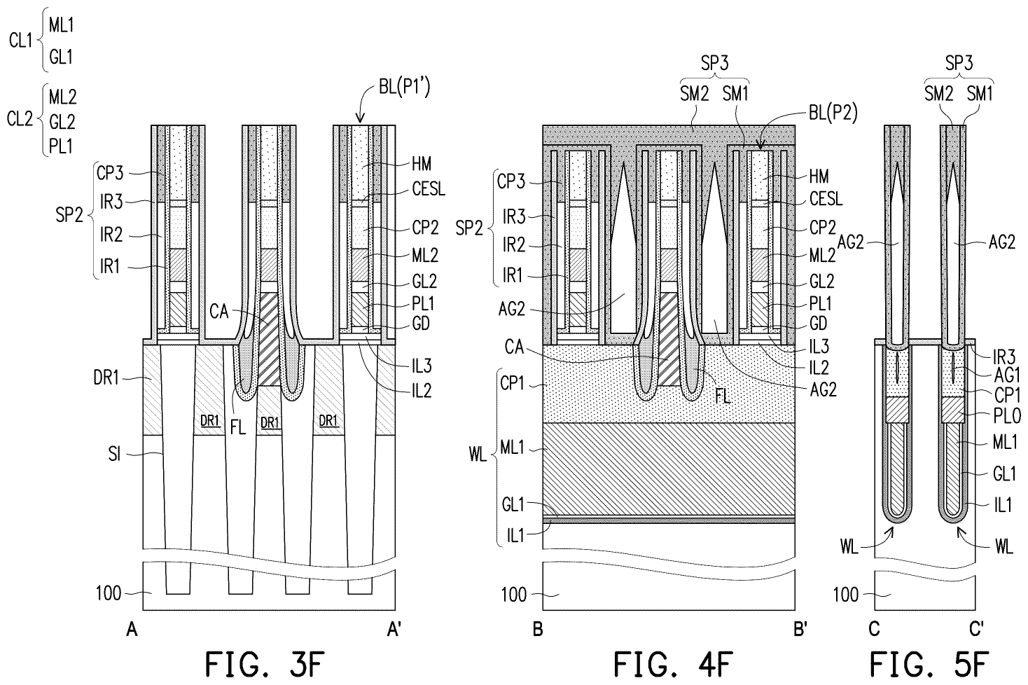

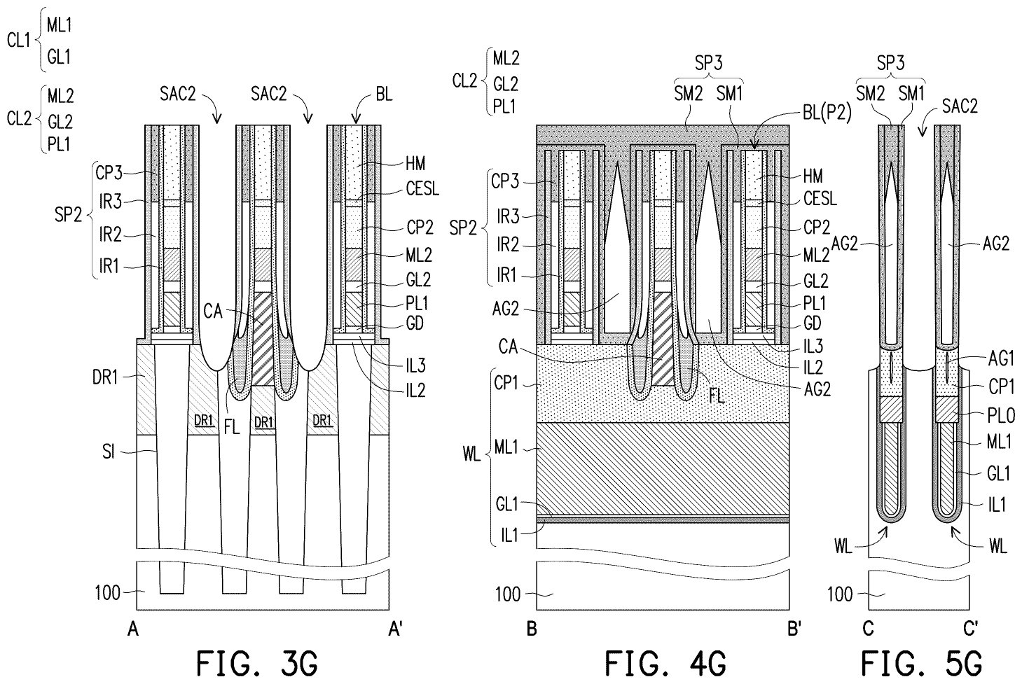

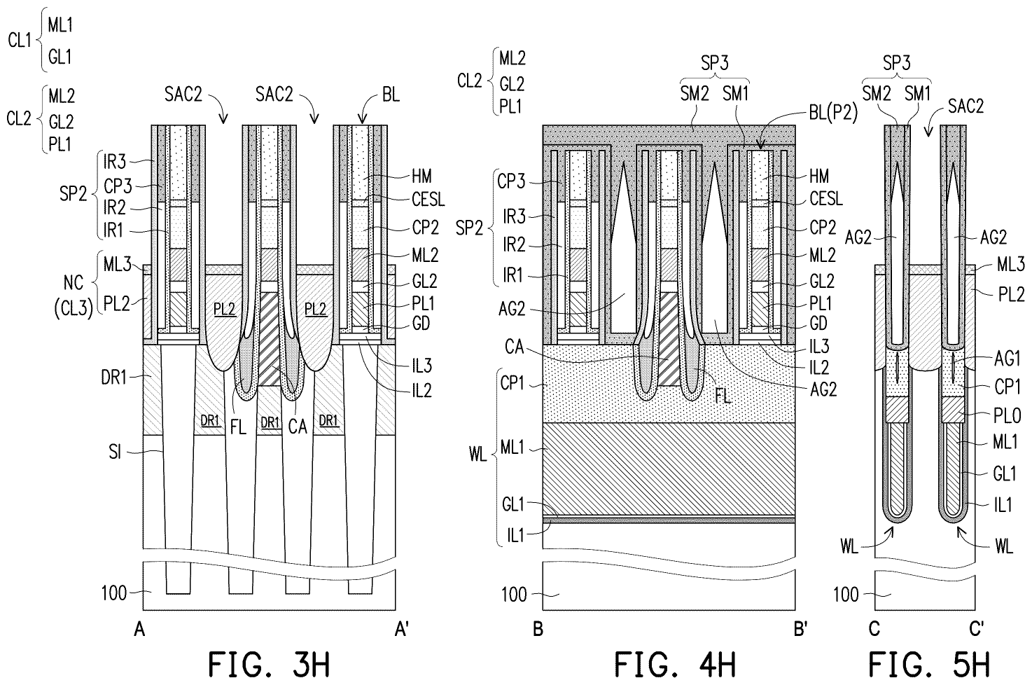

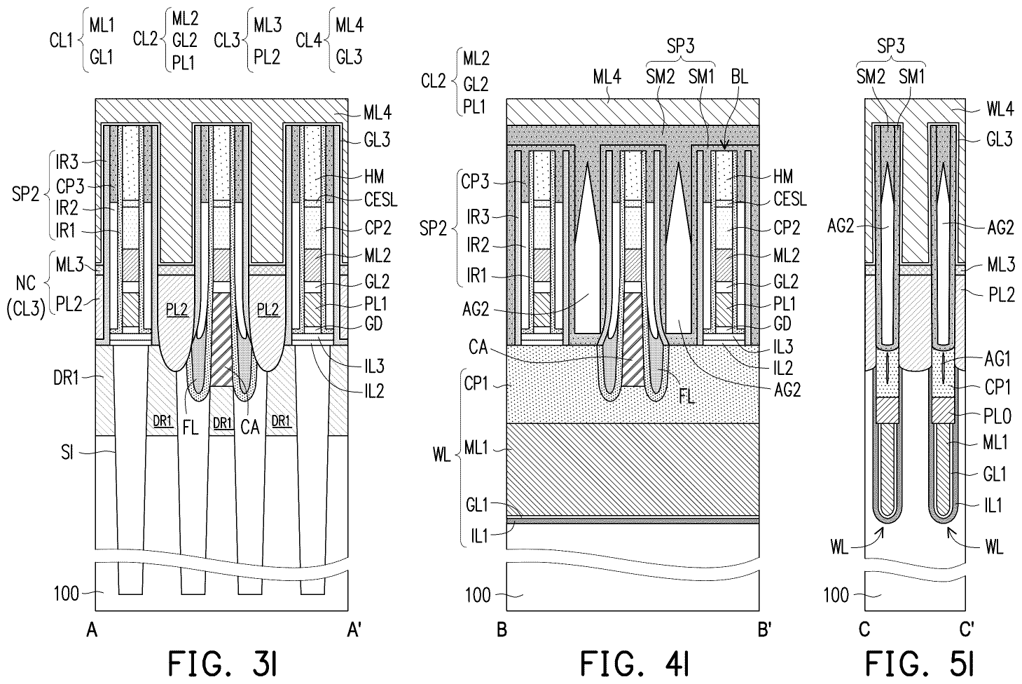

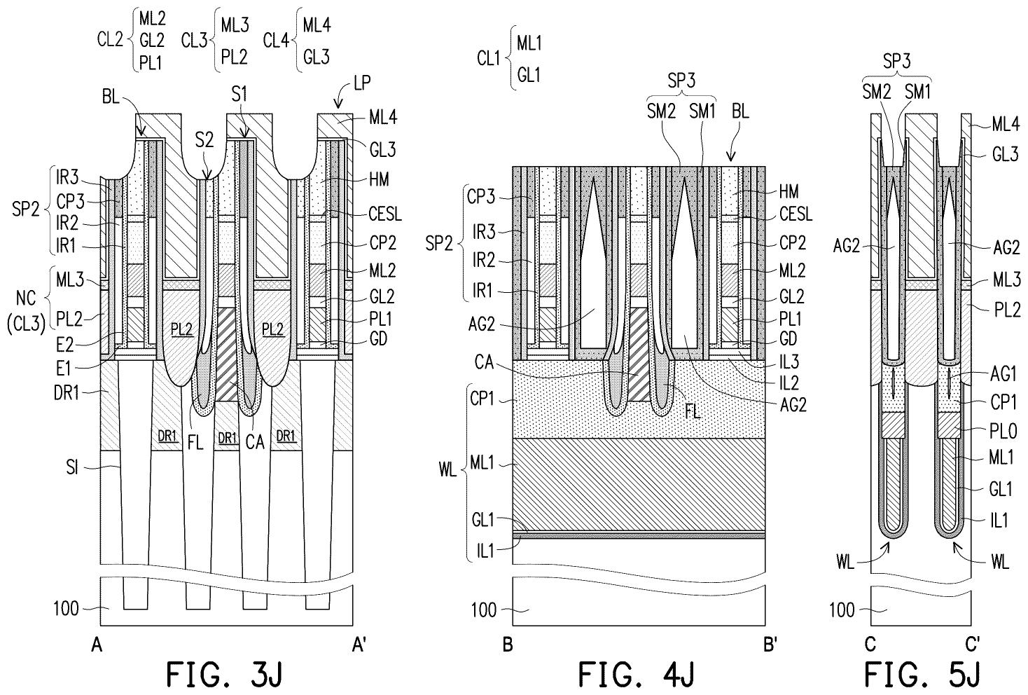

Referring to FIG. 2A, FIG. 3A, FIG. 4A, FIG. 5A and FIG. 2K, a lithography and etching process is performed to pattern the hard mask layer HM to the dielectric layer GD to form a plurality of bit line structures BL, and at the same time, the bit line plug BP is patterned to form a bit line contact CA. The bit line structures BL are arranged along the direction D1 and extended along the direction D2. The semiconductor layer PL1, the barrier layer GL2, and the metal layer ML2 in the bit line structures BL form a conductor layer CL2 of the bit line. The conductor layer CL2 of the bit line is electrically connected to the doped regions DR1 via the bit line contact CA. During the process of etching the semiconductor layer PL1 and the bit line plug BP, the insulating layer IL3 and the capping layer CP1 located below the semiconductor layer PL1 may be used as an etch stop layer. However, since a portion of the bit line plug BP is etched away, a groove R is formed at two sides of the bit line contact CA.

Referring to FIG. 2A, FIG. 3A, FIG. 4A, and FIG. 5A, after the bit line structures BL and the bit line contact CA are formed, a lining layer IR1, a filling layer FL, and an intermediate lining layer IR2 are formed in the sidewalls of the bit line structures BL and the grooves R. The lining layer IR1 is, for example, silicon oxynitride or silicon nitride. The intermediate lining layer IR2 is, for example, silicon oxide. The filling layer FL is, for example, silicon nitride. The method of forming of the lining layer IR1, the intermediate lining layer IR2, and the filling layer FL is as follows. The lining layer IR1 is formed on the substrate 100. Next, the filling layer FL is formed in the grooves R via deposition and anisotropic etching processes. Thereafter, the intermediate lining layer IR2 is formed on the substrate 100. Then, an anisotropic etching process is performed on the intermediate lining layer layers IR2 and IR1.

Then, the lining layer IR3 is formed on the substrate 100. The lining layer IR3 is, for example, silicon nitride. Then, the spaces between the bit line structures BL are filled with a sacrificial layer SL. The material of the sacrificial layer SL is different from the material of the lining layer IR3. The sacrificial layer SL is, for example, spin-on-glass, silicon oxide, or the like.

Referring to FIG. 2B, FIG. 3B, FIG. 4B, and FIG. 5B, a mask layer PR1 is formed on the substrate 100. The mask layer PR1 has a plurality of trenches T1 extended in the direction D1. Each of the trenches T1 exposes the sacrificial layer SL, the bit line structures BL, and the lining layer IR3 above the word line structures WL. Then, an etching process is performed to form self-aligned openings SAC1 in the sacrificial layer SL and the lining layer IR3. The self-aligned openings SAC1 expose the capping layer CP1 of the word line structures WL. During the etching process, the bit line structures BL and the lining layer IR3 not covered by the mask layer PR1, and the lining layer IR1 and the intermediate lining layer IR2 below the lining layer IR3 are also etched. Thus, a portion P2 and a spacer SP2 of the bit line structures BL with a lower height are formed. A height h2 of the portion P2 of the bit line structures BL is less than a height h1 of the original portion P1 of the bit line structures BL.

Referring to FIG. 2C, FIG. 3C, FIG. 4C, and FIG. 5C, an etching process (such as a wet etching process) is performed to remove the upper portion of the intermediate lining layer IR2 to form a trench G1 extended along the direction D2.

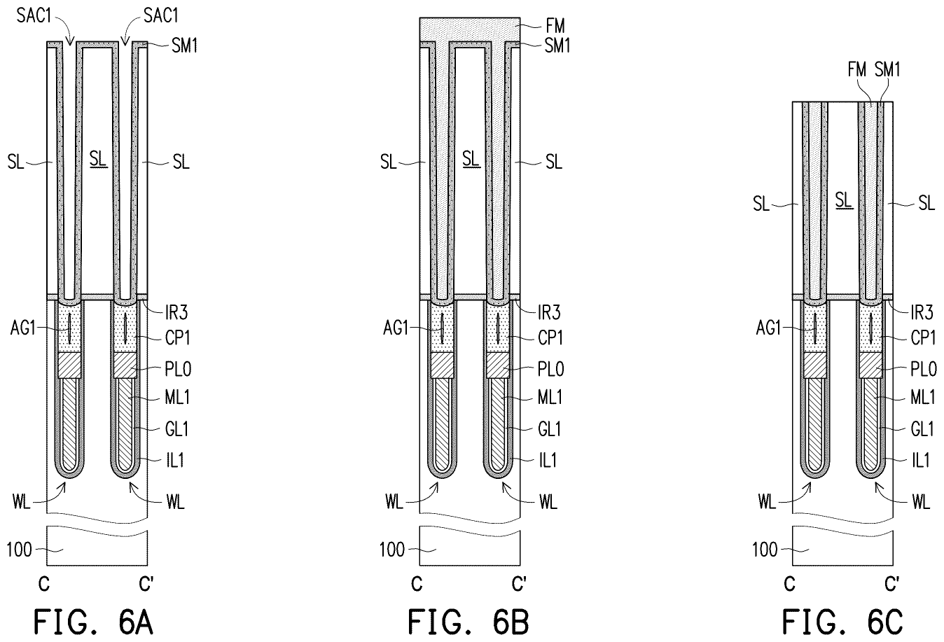

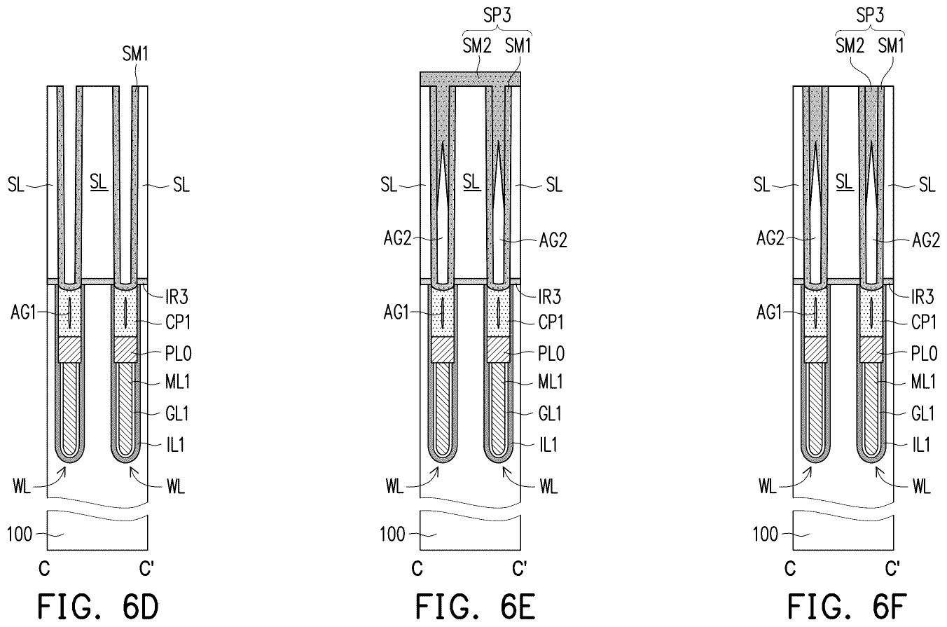

Referring to FIG. 2D, FIG. 3D, FIG. 4D, and FIG. 5D, the mask layer PR1 is removed. Then, a spacer SP3 is formed on the sacrificial layer SL and between the self-aligned openings SAC1 and the trench G1. The method of forming the spacer SP3 is as shown in FIG. 6A to FIG. 6F.

Referring to FIG. 6A, a spacer material SM1 is formed on the sacrificial layer SL and in the self-aligned openings SAC1 and the trench G1. The spacer material SM1 is, for example, silicon nitride, silicon oxynitride, or a combination thereof. The spacer material SM1 does not completely fill the self-aligned openings SAC1, leaving a remaining space. The spacer material SM1 is, for example, a conformal layer.

Referring to FIG. 6B, a filling material FM is formed on the spacer material SM1 and in the remaining space of the self-aligned openings SAC1. The filling material

FM may be silicon oxide or polymer (such as photoresist).

Referring to FIG. 6C, a planarization process is performed to remove a portion of the sacrificial layer SL, a portion of the filling material FM, and a portion of the spacer material SM1.

Referring to FIG. 6D, the filling material FM is removed to expose the spacer material SM1 in the self-aligned openings SAC1. The filling material FM may be wet etching or oxidation ashing.

Referring to FIG. 6E, a spacer material SM2 is formed on the sacrificial layer SL and in the self-aligned openings SAC1. The spacer material SM2 seals the top portion of the self-aligned openings SAC1 and does not completely fill the self-aligned openings SAC1. The spacer material SM2 is, for example, silicon nitride, silicon oxynitride, or a combination thereof.

Referring to FIG. 6F and FIG. 2E to FIG. 6E, a removal process, such as a chemical mechanical polishing process or an etch-back process, is performed to remove the redundant spacer SP3 until the sacrificial layer SL is exposed. In order to ensure that the sacrificial layer SL may be exposed, during the removal process, the original portion P1 of the bit line structures BL may be partially removed to form a portion P1′ having a height of h1′. The height h1′ of the portion P1′ of the bit line structures BL may be equal to or greater than the height h2 of the portion P2 of the bit line structures BL. The spacer material SM1 and the spacer material SM2 jointly form the spacers SP3. The plurality of spacers SP3 are located directly above the plurality of word line structures WL. The spacers SP3 have air gaps AG2 therein. The air gaps AG2 are covered by the spacer material SM1, and the top portion of the air gaps AG2 is covered and sealed by the spacer material SM2. The top portion of the air gaps AG2 has a sloped sidewall, and the bottom portion thereof has a flatter surface than the top portion. The bottom width of the air gaps AG2 is greater than the top width thereof. The space volume of the air gaps AG2 is greater than the space volume of the air gaps AG1. The air gaps AG2 are located directly above the word line structures WL. The spacers SP3 are also extended to the sidewall of the bit line structures BL, the bottom portions of two spacers SP3 of two adjacent bit line structures BL are connected, and the plurality of air gaps AG2 are also extended down to the side of the plurality of bit line structures BL, as shown in FIG. 4E.

Referring to FIG. 2G, FIG. 3G, FIG. 4G, and FIG. 5G, the lining layer IR3 is subjected to an etching process, such as an anisotropic etching process, to form the self-aligned openings SAC2. The self-aligned openings SAC2 are used as node contact openings, exposing the doped regions DR1 located at two sides of two adjacent word line structures WL in the substrate 100.

Referring to FIG. 2H, FIG. 3H, FIG. 4H, and FIG. 5H, next, node contacts NC are formed in the self-aligned openings SAC2. The material of the node contacts NC includes a conductor layer CL3. The conductor layer CL3 includes, for example, a semiconductor layer PL2 and a metal layer ML3. The semiconductor layer PL2 may be a doped polysilicon layer. The metal layer ML3 may be metal silicide, such as cobalt silicide. The method of forming the node contacts NC is, for example, depositing a doped polysilicon material layer above the substrate 100 to be filled into the self-aligned openings SAC2, and then performing an anisotropic etching process to form the semiconductor layer PL2. Next, a self-aligned metal silicide process is performed to form the metal layer ML3 made of metal silicide on the semiconductor layer PL2.

Referring to FIG. 1C, FIG. 2I, FIG. 3I, FIG. 4I, and FIG. 5I, a conductor layer CL4 is formed above the substrate 100. The conductor layer CL4 includes, for example, a barrier layer GL3 and a metal layer ML4. The material of the barrier layer GL3 is, for example, titanium, titanium nitride, tantalum, tantalum nitride, or a combination thereof. The material of the metal layer ML4 is, for example, tungsten. Since the top portion of the air gaps AG2 is completely sealed by the spacers SP3, the barrier layer GL3 does not fall into the air gaps AG2 to cause an electrical issue.

Referring to FIG. 2J, FIG. 3J, FIG. 4J, and FIG. 5J, a lithography and etching process is performed to pattern the conductor layer CL4, thereby forming capacitor landing pads LP. The capacitor landing pads LP are formed on and electrically connected to the node contacts NC. The capacitor landing pads LP are overlapped with a portion of the node contacts NC and overlapped with a portion of the spacer SP2 and a portion of the hard mask layer HM of the bit line structures BL. Since the barrier layer GL3 does not fall into the air gaps AG2, the capacitor landing pads LP are electrically isolated from each other.

Referring to FIG. 2K, capacitors C are formed on the capacitor landing pads LP. The capacitors C are electrically connected to the doped regions DR1 in the substrate 100 via the capacitor landing pads LP and the node contacts NC.

Referring to FIG. 2H, in the present embodiment, the top portions and the bottom portions of two spacers SP3 of two adjacent node contacts NC are connected to each other to form the air gaps AG2. The plurality of air gaps AG2 are located directly above the plurality of word line structures WL. Each of the air gaps AG2 is located within the range surrounded by two adjacent node contacts NC and two adjacent bit line structures BL. One side of each of the bit line structures BL includes the plurality of air gaps AG2 separated from each other. In the direction D2 in which the plurality of bit lines are extended, the plurality of air gaps AG2 and the plurality of node contacts NC alternate with each other. In the direction D1 in which the word line structures WL are extended, the plurality of air gaps AG2 and the plurality of bit line structures BL alternate with each other. The plurality of air gaps AG2 are separated from each other and arranged in an array.

Based on the above, in an embodiment of the invention, the bottom portions and the top portions of the sidewalls of two adjacent node contacts and the spacers of the sidewalls of two adjacent bit lines are connected to form the air gaps, and therefore the DRAM may be made to have lower parasitic capacitance. In addition, the barrier layer of the capacitor landing pads does not fall into the air gaps, so the capacitor landing pads are electrically isolated from each other.

What is claimed is:

1. A dynamic random access memory, comprising:
a plurality of word line structures located in a substrate;
a plurality of bit line structures located above the substrate and spanning the plurality of word line structures;
a plurality of node contacts, wherein each of the plurality of node contacts is located between two adjacent word structures and two adjacent bit line structures; and
a plurality of spacers located on a plurality of sidewalls of the plurality of node contacts,
wherein top portions and bottom portions of two spacers of two adjacent node contacts are connected to each other to form a plurality of first air gaps.

2. The dynamic random access memory of claim 1, wherein the plurality of first air gaps are located directly above the plurality of word line structures.

3. The dynamic random access memory of claim 1, wherein the plurality of spacers are extended between the plurality of bit line structures, bottom portions of two spacers of two adjacent bit line structures are connected, and the plurality of first air gaps are extended downward to a side of the plurality of bit line structures.

4. The dynamic random access memory of claim 1, wherein each of the first air gaps is located within a range enclosed by two adjacent node contacts and two adjacent bit line structures.

5. The dynamic random access memory of claim 1, wherein one side of each of the bit line structures comprises the plurality of first air gaps separated from each other.

6. The dynamic random access memory of claim 1, wherein each of the word line structures comprises:
a conductor layer located in the substrate;
a capping layer located on the conductor layer; and
an insulating layer covering the conductor layer and a surrounding of the capping layer,
wherein the capping layer comprises a second air gap.

7. The dynamic random access memory of claim 1, wherein a bottom width of the plurality of first air gaps is greater than a top width of the plurality of first air gaps.

8. The dynamic random access memory of claim 1, wherein in a direction where the plurality of bit line structures are extended, the plurality of first air gaps and the plurality of node contacts alternate with each other.

9. The dynamic random access memory of claim 1, wherein in a direction where the plurality of word line structures are extended, the plurality of first air gaps and the plurality of bit line structures alternate with each other.

10. The dynamic random access memory of claim 1, wherein the plurality of first air gaps are arranged in an array.

11. A method of fabricating a dynamic random access memory, comprising:
forming a plurality of word line structures located in a substrate;
forming a plurality of bit line structures located above the substrate;
forming a plurality of node contacts, wherein each of the plurality of node contacts is located between two adjacent word structures and two adjacent bit line structures; and
forming a plurality of spacers located at a plurality of sidewalls of the plurality of node contacts,
wherein top portions and bottom portions of two spacers of two adjacent node contacts are connected to each other to form a plurality of first air gaps.

12. The method of fabricating the dynamic random access memory of claim 11, wherein the plurality of first air gaps are formed directly above the plurality of word line structures.

13. The method of fabricating the dynamic random access memory of claim 11, wherein the plurality of spacers are further extended to a plurality of sidewalls of the plurality of bit line structures, and bottom portions of two spacers of two adjacent bit line structures are connected, wherein the plurality of first air gaps are extended downward to a side of the plurality of bit line structures.

14. The method of fabricating the dynamic random access memory of claim 11, wherein forming the plurality of spacers comprises:
forming a sacrificial layer on the substrate and between the plurality of bit line structures;
forming a plurality of self-aligned openings in the sacrificial layer;
forming a first spacer material at the dielectric layer and a sidewall and a bottom surface of the plurality of self-aligned openings, and the first spacer material does not completely fill the plurality of openings;
forming a sacrificial layer on the first spacer material, and filling the sacrificial layer in a remaining space of the plurality of self-aligned openings;
performing a first planarization process to remove the first spacer material and the sacrificial layer on the dielectric layer;
removing the sacrificial layer in the plurality of openings;
forming a second spacer material on the dielectric layer such that the second spacer material seals a top portion of the plurality of self-aligning openings; and
performing a second planarization process to remove the second spacer material on the dielectric layer, wherein the first spacer material and the second spacer material form the spacer layer and the plurality of air gaps.

15. The method of fabricating the dynamic random access memory of claim 14, wherein a bottom width of the plurality of first air gaps is greater than a top width of the plurality of first air gaps.

16. The method of fabricating the dynamic random access memory of claim 11, wherein each of the first air gaps is located within a range enclosed by two adjacent node contacts and two adjacent bit line structures.

17. The method of fabricating the dynamic random access memory of claim 11, wherein in a direction where the plurality of bit line structures are extended, the plurality of first air gaps and the plurality of node contacts alternate with each other.

18. The method of fabricating the dynamic random access memory of claim 11, wherein in a direction where the plurality of word line structures are extended, the plurality of first air gaps and the plurality of bit line structures alternate with each other.

19. The method of fabricating the dynamic random access memory of claim 11, wherein one side of each of the bit line structures comprises a plurality of first air gaps separated from each other.

20. The method of fabricating the dynamic random access memory of claim 11, wherein each of the word line structures comprises:
a conductor layer located in the substrate;
a capping layer located on the conductor layer; and
an insulating layer covering the conductor layer and a surrounding of the capping layer,
wherein the capping layer comprises a second air gap.
